(19) United States
(12) Patent Application Publication
(10) Pub. No.: US 2026/0129874 A1
(43) Pub. Date: May 7, 2026

(54) SEMICONDUCTOR PACKAGE

(71) Applicant: SAMSUNG ELECTRONICS CO., LTD., Suwon-si (KR)

(72) Inventors: Hongjin Kim, Suwon-si (KR); Kihong Jeong, Suwon-si (KR); Dongok Kwak, Suwon-si (KR)

(21) Appl. No.: 19/219,770

(22) Filed: May 27, 2025

(30) Foreign Application Priority Data
Nov. 6, 2024 (KR) 10-2024-0156041

(51) Int. Cl. H01L 23/00; H01L 25/065; H10B 80/00

(52) U.S. Cl. CPC H10B 80/00; H10W 90/00; H10W 72/5449; H10W 72/923; H10W 72/932; H10W 72/9415; H10W 72/9445; H10W 90/24; H10W 90/752; H10W 90/754

(57) ABSTRACT

An example semiconductor package includes a package substrate including a plurality of bonding pads; a plurality of semiconductor chips mounted on an upper surface of the package substrate and including a plurality of pads, respectively, where each of the plurality of pads includes first to eighth data pads; and a plurality of wires connecting the plurality of pads, respectively, where the plurality of semiconductor chips include first to fourth semiconductor chips, the first to fourth data pads included in the first semiconductor chip and the first to fourth data pads included in the second semiconductor chip are connected to each other through first to fourth wires, respectively, and the first to fourth wires are separated from the third semiconductor chip and the fourth semiconductor chip.

### CROSS-REFERENCE TO RELATED APPLICATION

This application claims benefit of priority to Korean Patent Application No. 10-2024-0156041 filed on Nov. 6, 2024, in the Korean Intellectual Property Office, the disclosure of which is incorporated herein by reference in its entirety.

### BACKGROUND

A semiconductor package may include a package substrate and at least one semiconductor chip mounted on the package substrate, and a plurality of pads included in the semiconductor chip may be electrically connected to a plurality of bonding pads included in the package substrate in a wired manner. In a semiconductor package including a memory chip, a method of stacking two or more semiconductor chips on a package substrate has been proposed to increase storage capacity of the semiconductor package. While such a structure may efficiently increase storage capacity of the semiconductor package, input/output capacitance of the pads connected to the wires may increase, as the semiconductor chips are connected through each wire.

### SUMMARY

The present disclosure relates to a semiconductor package having improved reliability and advantageous for high-speed operations by reducing a magnitude of input/output capacitance affecting input/output of a data signal by memory chips.

In some implementations, a semiconductor package includes a package substrate including a plurality of bonding pads; a plurality of semiconductor chips mounted on an upper surface of the package substrate and including a plurality of pads, respectively, wherein each of the plurality of pads includes first to eighth data pads; and a plurality of wires connecting the plurality of pads, respectively, wherein the plurality of semiconductor chips include first to fourth semiconductor chips, the first to fourth data pads included in the first semiconductor chip and the first to fourth data pads included in the second semiconductor chip are connected to each other through first to fourth wires, respectively, and the first to fourth wires are separated from the third semiconductor chip and the fourth semiconductor chip.

In some implementations, a semiconductor package includes a package substrate including a plurality of bonding pads; a plurality of semiconductor chips mounted on an upper surface of the package substrate and including a plurality of pads, respectively, wherein each of the plurality of pads includes first to eighth data pads; and a plurality of wires connecting the plurality of pads, respectively, wherein the plurality of semiconductor chips include first to fourth semiconductor chips, the first to fourth data pads included in the first semiconductor chip and the first to fourth data pads included in the second semiconductor chip are respectively connected to each other through first to fourth wires, wherein the first to fourth wires are separated from the third semiconductor chip and the fourth semiconductor chip, the fifth to eighth data pads included in the third semiconductor chip and the fifth to eighth data pads included in the fourth semiconductor chip are respectively connected to each other through fifth to eighth wires, wherein the fifth to eighth wires are separated from the first semiconductor chip and the second semiconductor chip, and lengths of the first to fourth wires are different from lengths of the fifth to eighth wires.

In some implementations, a semiconductor package includes a package substrate including a plurality of bonding pads; a plurality of semiconductor chips mounted on an upper surface of the package substrate and including a plurality of pads, respectively, wherein each of the plurality of pads includes first to eighth data pads; and a plurality of wires connecting the plurality of pads, respectively, wherein the plurality of semiconductor chips include first to fourth semiconductor chips, the first to fourth data pads included in the first semiconductor chip and the first to fourth data pads included in the second semiconductor chip are connected to each other through first to fourth wires, respectively, wherein the first to fourth wires are separated from the third semiconductor chip and the fourth semiconductor chip, and the plurality of semiconductor chips receive the same clock signal through at least one wire, and, based on the clock signal, the first semiconductor chip and the second semiconductor chip transmit a first data signal through the first to fourth data pads, and simultaneously, the third semiconductor chip and the fourth semiconductor chip transmit a second data signal through the fifth to eighth data pads.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a block diagram schematically illustrating an example of a system.

FIG. 2 is a cross-sectional view schematically illustrating an example of a semiconductor package.

FIG. 3 is a plan view schematically illustrating an example of a semiconductor package.

FIG. 4 is a cross-sectional view illustrating an example of a cross-section of FIG. 3 in an A-A′ direction.

FIG. 5 is a cross-sectional view illustrating an example of a cross-section of FIG. 3 in a B-B′ direction.

FIG. 6 is a plan view illustrating an example of a semiconductor package.

FIG. 7 is a cross-sectional view illustrating an example of a cross-section of FIG. 6 in a C-C′ direction.

FIG. 8 is a cross-sectional view illustrating an example of a cross-section of FIG. 6 in a D-D′ direction.

FIG. 9 is a plan view illustrating an example of a semiconductor package.

FIG. 10 is a cross-sectional view illustrating an example of a cross-section of FIG. 9 in an E-E′ direction.

FIG. 11 is a cross-sectional view illustrating an example of a cross-section of FIG. 9 in an F-F′ direction.

FIGS. 12 and 13 are plan views illustrating an example of a semiconductor package.

FIG. 14 is a block diagram illustrating an example of a memory device.

### DETAILED DESCRIPTION

Hereinafter, some implementations will be described as follows with reference to the attached drawings.

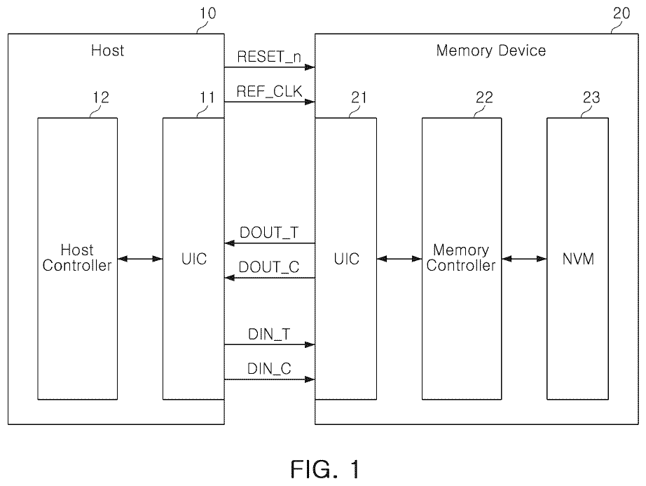

FIG. 1 is a block diagram schematically illustrating an example of a system.

Referring to FIG. 1, a system may be a storage system following a UFS standard announced by a joint electron device engineering council (JEDEC), and may include a host 10 and a memory device 20. The system is not necessarily limited to the storage system following the UFS standard, and the host 10 and the memory device 20 may exchange data in a manner, different from that of the UFS standard.

The host 10 may include a host controller 12, an application, a host driver, a host memory, and a UFS interconnect (UIC) layer 11. The host 10 may control an overall operation of a semiconductor device, specifically, operations of other components that make up the semiconductor device.

The memory device 20 may function as a non-volatile storage device storing data regardless of whether power is supplied thereto, and may have a relatively large amount of storage capacity. The memory device 20 may include a UIC layer 21, a memory controller 22, a non-volatile memory 23, and the like. An input signal and an output signal may be transmitted and received through the UIC layer 11 of the host 10 and the UIC layer 21 of the memory device 20. Referring to FIG. 1, the memory controller 22 and the UIC layer 21 are illustrated separately, but are not limited thereto, and the UIC layer 21 may be included in the memory controller 22. In addition, as described above, when a communication method of the host 10 and the memory device 20 does not follow the UFS standard, the UIC layers 11 and 21 may be replaced with other interfaces.

The memory device 20 may include the memory controller 22 and the non-volatile memory 23 storing data under control of the memory controller 22. The non-volatile memory 23 may be formed as a plurality of memory units, and such memory units may include a vertical NAND (V-NAND) flash memory of a 2D structure or a 3D structure, but may also include other types of non-volatile memory such as a PRAM and/or a RRAM, or the like.

The memory device 20 may be included in the semiconductor device while being physically separated from the host 10, or may be implemented in the same package as the host 10. In addition, the memory device 20 may have a form such as a solid state device (SSD) or a memory card. Such a memory device 20 may be a device to which a standard specification such as a UFS, an embedded multi-media card (eMMC), or a non-volatile memory express (NVMe) is applied, but is not necessarily limited thereto.

Between the host 10 and the memory device 20, a line transmitting a reference clock REF_CLK, a line transmitting a hardware reset signal RESET_n for the memory device 20, a pair of lines transmitting a differential input signal pair DIN_T and DIN_C, and a pair of lines transmitting a differential output signal pair DOUT_T and DOUT_C may be included. Referring to FIG. 1, a pair of lines transmitting a differential input signal pair DIN_T and DIN_C may constitute a reception lane, and a pair of lines transmitting a differential output signal pair DOUT_T and DOUT_C may constitute a transmission lane.

The reception lane and the transmission lane may transmit data in a serial communication manner, and full-duplex communication between the host 10 and the memory device 20 may be possible due to a structure in which the reception lane and the transmission lane may be separated. For example, the memory device 20 may transmit data to the host 10 through the transmission lane while receiving data from the host 10 through the reception lane.

VCC, VCCQ, VCCQ2, or the like may be input as power voltages to the memory device 20. VCC may be a main power voltage for the memory device 20, and may have a value of 2.4 to 3.6 V. VCCQ may be a power voltage for supplying a low range of voltage, may be mainly for the memory controller 22, and may have a value of 1.14 to 1.26 V. VCCQ2 may be a power voltage for supplying a voltage lower than VCC but higher than VCCQ, may be mainly for an input/output interface such as MIPI M-PHY, and may have a value of 1.7 to 1.95 V.

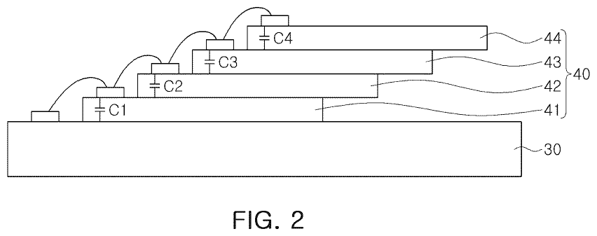

In some implementations, the non-volatile memory 23 may have a structure in which two or more semiconductor chips are stacked on a package substrate to increase storage capacity of the semiconductor package. In this structure, while the storage capacity of the semiconductor package may efficiently increase, input/output capacitance of pads connected to wires may increase, as the semiconductor chips are connected through each wire. Therefore, there may be a limit to inputting and outputting a signal at a high speed. This may be described in detail in FIG. 2 below.

FIG. 2 is a cross-sectional view schematically illustrating an example of a semiconductor package.

A semiconductor package may include a package substrate 30 and a plurality of semiconductor chips 40. The plurality of semiconductor chips 40 may be mounted on an upper surface of the package substrate 30, and may be stacked in a direction, perpendicular to the upper surface of the package substrate 30. By stacking the plurality of semiconductor chips 40 on the upper surface of the package substrate 30, capacity of a memory may increase. Capacitance may be formed between the plurality of stacked semiconductor chips 40.

Referring to FIG. 2, the plurality of semiconductor chips 40 may include first to fourth semiconductor chips 41 to 44. The first to fourth semiconductor chips 41 to 44 may be stacked in a stepwise manner on the upper surface of the package substrate 30. Each of the first to fourth semiconductor chips 41 to 44 may include at least one data pad, and the data pad may be commonly connected to a bonding pad of the package substrate 30 by a wire. In each of the first to fourth semiconductor chips 41 to 44, the data pad may be connected to a receiver receiving a data signal and a driver transmitting the data signal, and therefore, predetermined capacitance C1 to C4 may exist in the data pad.

Assuming an operation in which a data signal is input to the data pad of the first semiconductor chip 41, an external memory controller or the like may transmit the data signal to the data pad of the first semiconductor chip 41 by the wire. The wire may be connected to the data pads of each of the second to fourth semiconductor chips 42 to 44, in addition to the first semiconductor chip 41, and therefore, not only first capacitance C1 but also second to fourth capacitances C2 to C4 may act as a load for a circuit that transmits the data signal to the first semiconductor chip 41. As a result, input/output capacitance that should be driven in the circuit that transmits the data signal to the first semiconductor chip 41 has no choice but to increase, and as a result, an eye margin of the data signal may decrease or current consumption required to transmit the data signal may increase.

In some implementations, a semiconductor package advantageous for a high-speed operation may be implemented by reducing the number of semiconductor chips 41 to 44 commonly connected to one bonding wire. For example, when the plurality of semiconductor chips 41 to 44 include the first to eighth data pads, respectively, first to fourth data pads respectively included in the first and second semiconductor chips 41 and 42 may be electrically separated from first to fourth data pads respectively included in the third and fourth semiconductor chips 43 and 44. Therefore, an input/output operation of a data signal through the first to fourth data pads included in the first semiconductor chip 41 or the second semiconductor chip 42 may be performed at a high speed, and performance of the semiconductor package may be improved by increasing the eye margin of the data signal.

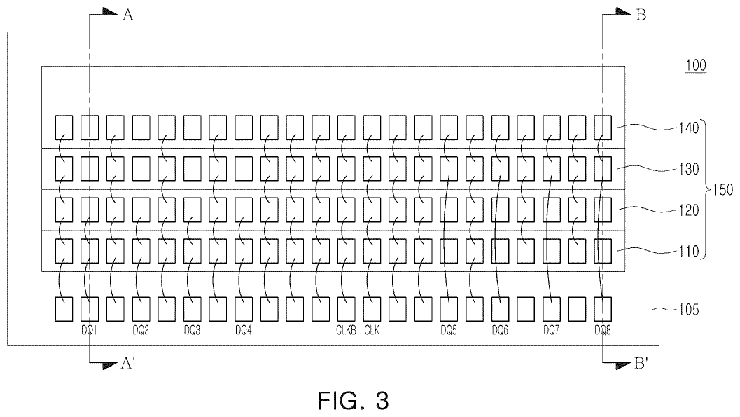

FIG. 3 is a plan view schematically illustrating an example of a semiconductor package.

A semiconductor package 100 may include a package substrate 105, a plurality of semiconductor chips 150, and a plurality of wires. The plurality of semiconductor chips 150 may be mounted on an upper surface of the package substrate 105.

The package substrate 105 may use various types of substrates such as a printed circuit board (PCB), a flexible substrate, a tape substrate, or the like. As an example, the package substrate 105 may be a printed circuit board (PCB) having an internal wiring formed therein. The package substrate 105 may include a plurality of bonding pads disposed on an upper surface thereof, and connection pads disposed on a lower surface thereof. The plurality of bonding pads may be electrically connected to the connection pads through the internal wiring. Connection terminals such as solder balls or solder bumps may be attached to the connection pads.

The plurality of semiconductor chips 150 may be stacked on the upper surface of the package substrate 105. Each of the plurality of semiconductor chips 150 may include a plurality of pads. The plurality of pads may include a power voltage pad connected to a power voltage, a ground voltage pad connected to a ground voltage, and a data pad transmitting data. In some implementations, the plurality of pads may be respectively disposed on upper surface edges of the plurality of semiconductor chips 150. In addition, the plurality of semiconductor chips 150 may be stacked in a stepwise manner in a first direction, perpendicular to the upper surface of the package substrate 105, such that the upper surface edges of the plurality of semiconductor chips 150 may be exposed. Therefore, the plurality of pads may be exposed upward.

In some implementations, the plurality of semiconductor chips 150 may include first to eighth data pads DQ1 to DQ8, respectively. In some implementations, the first to eighth data pads DQ1 to DQ8 included in the plurality of semiconductor chips 150 may not be adjacent to each other. At least one pad providing a power voltage or a ground voltage may be disposed between the first to eighth data pads DQ1 to DQ8. The power voltage may be one of VCC, which may be a main power voltage for driving a memory including the semiconductor package 100, VCCQ, which may be a power voltage for driving a memory controller, or VCCQ2, which may be a power voltage for an input/output interface.

In some implementations, the plurality of pads may include a pair of pads providing a differential clock signal CLK and CLKB. Clock signal CLK pads included in each of the plurality of semiconductor chips may be connected to each other through at least one wire, and the plurality of semiconductor chips 150 may transmit data through the first to eighth data pads DQ1 to DQ8 at the same timing.

In some implementations, the pair of pads providing the differential clock signal CLK and CLKB may be disposed between the fourth data pad DQ4 and the fifth data pad DQ5. At least one pad providing a power voltage or a ground voltage may be disposed between the fourth data pad DQ4 and the pair of pads, and at least one pad providing a power voltage or a ground voltage may also be disposed between the fifth data pad DQ5 and the pair of pads. Referring to FIG. 3, three pads providing a power voltage or a ground voltage may be disposed between the fourth data pad DQ4 and the pair of pads, and two pads providing a power voltage or a ground voltage may be disposed between the fifth data pad DQ5 and the pair of pads.

The plurality of wires may electrically connect a plurality of pads included in the plurality of semiconductor chips, respectively. A plurality of bonding wires may electrically connect the plurality of bonding pads and the plurality of pads, respectively. In some implementations, the plurality of wires and the plurality of bonding wires may be a metal wire, such as a gold wire, a copper wire, or an aluminum wire.

Storage capacity of a semiconductor package 100 may increase by stacking the plurality of semiconductor chips 150, but as the plurality of semiconductor chips 150 may be connected through each of the wires, input/output capacitance of a pad connected to a wire may increase. Therefore, reliability of the semiconductor package 100 may be reduced or there may be a limit to inputting and outputting a signal at a high speed.

In some implementations, the plurality of semiconductor chips 150 may include first to fourth semiconductor chips 110, 120, 130, and 140. Each of the plurality of semiconductor chips 150 may include the first to eighth data pads DQ1 to DQ8. Assuming an operation in which a data signal is input to the first data pad DQ1 of the first semiconductor chip 110, an external memory controller or the like may transmit a data signal to the first data pad DQ1 of the first semiconductor chip 110 through a first wire. The first wire may be connected to the first data pad DQ1 of the first semiconductor chip 110 and the first data pad DQ1 of the second semiconductor chip 120, and may be electrically separated from the first data pad DQ1 of the third semiconductor chip 130 and the first data pad DQ1 of the fourth semiconductor chip 140. Therefore, the first wire may be subject to capacitance due to an internal circuit of the first semiconductor chip 110 and capacitance due to an internal circuit of the second semiconductor chip 120 as loads, and may not be affected by capacitance due to an internal circuit of the third semiconductor chip 130 and capacitance due to an internal circuit of the fourth semiconductor chip 140. The same may be applied to second to fourth wires connecting the second to fourth data pads DQ2 to DQ4 included in the first semiconductor chip 110 and the second semiconductor chip 120.

In some implementations, assuming an operation in which a data signal is input to the fifth data pad DQ5 of the third semiconductor chip 130, an external memory controller or the like may transmit a data signal to the fifth data pad DQ5 of the third semiconductor chip 130 through a fifth wire. The fifth wire may be connected to the fifth data pad DQ5 of the third semiconductor chip 130 and the fifth data pad DQ5 of the fourth semiconductor chip 140, and may be electrically separated from the fifth data pad DQ5 of the first semiconductor chip 110 and the fifth data pad DQ5 of the second semiconductor chip 120. Therefore, the fifth wire may be subject to capacitance due to an internal circuit of the third semiconductor chip 130 and capacitance due to an internal circuit of the fourth semiconductor chip 140 as loads, and may not be affected by capacitance due to an internal circuit of the first semiconductor chip 110 and capacitance due to an internal circuit of the second semiconductor chip 120. The same may be applied to sixth to eighth wires connecting the sixth to eighth data pads DQ6 to DQ8 included in the third semiconductor chip 130 and the fourth semiconductor chip 140.

Therefore, an input/output operation of a data signal through the first to fourth data pads DQ1 to DQ4 included in the first semiconductor chip 110 or the second semiconductor chip 120, and an input/output operation of a data signal through the fifth to eighth data pads DQ5 to DQ8 included in the third semiconductor chip 130 or the fourth semiconductor chip 140 may be performed at a high speed, and performance of the semiconductor package may be improved by increasing an eye margin of a data signal.

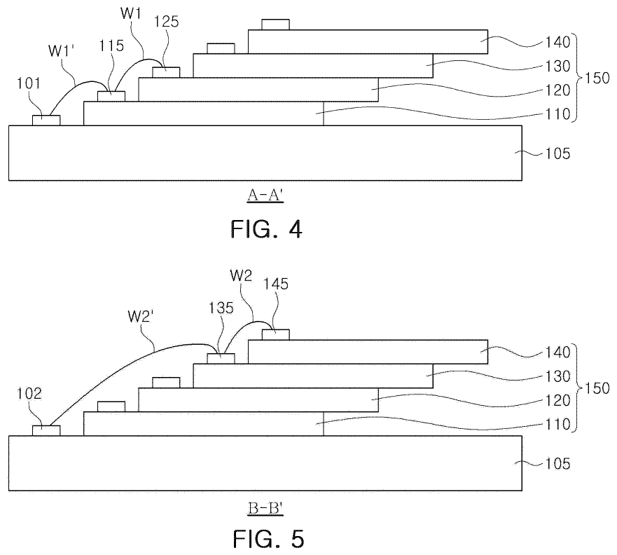

FIG. 4 is a cross-sectional view illustrating an example of a cross-section of FIG. 3 in a A-A′ direction.

In some implementations, the plurality of semiconductor chips 150 may have a structure in which they are stacked in a stepwise manner on the upper surface of the package substrate 105 in the first direction, perpendicular to the upper surface of the package substrate 105. The plurality of semiconductor chips 150 may be stacked in sequence of the first semiconductor chip 110, the second semiconductor chip 120, the third semiconductor chip 130, and the fourth semiconductor chip 140.

In some implementations, a lower surface of the second semiconductor chip 120 may be in contact with an upper surface of the first semiconductor chip 110. A lower surface of the fourth semiconductor chip 140 may be in contact with an upper surface of the third semiconductor chip 130. Referring to FIG. 4, a lower surface of the third semiconductor chip 130 may be in contact with an upper surface of the second semiconductor chip 120, a lower surface of the first semiconductor chip 110 may be in contact with an upper surface of the fourth semiconductor chip 140.

In some implementations, in the first direction, perpendicular to the upper surface of the package substrate 105, the first semiconductor chip 110 and the second semiconductor chip 120 may be disposed on a lowermost end among the plurality of semiconductor chips 150, and the third semiconductor chip 130 and the fourth semiconductor chip 140 may be disposed on an uppermost end among the plurality of semiconductor chips 150. In the first direction, the first semiconductor chip 110 may be in contact with the upper surface of the package substrate 105, and the fourth semiconductor chip 140 may be disposed farthest from the package substrate 105 among the plurality of semiconductor chips 150. In some implementations, in the first direction, the first semiconductor chip 110 and the second semiconductor chip 120 may be disposed on an uppermost end among the plurality of semiconductor chips 150, and the third semiconductor chip 130 and the fourth semiconductor chip 140 may be disposed on a lowermost end among the plurality of semiconductor chips 150.

In some implementations, first to fourth data pads included in the first semiconductor chip 110 and first to fourth data pads included in the second semiconductor chip 120 may be electrically connected to each other through first to fourth wires, respectively, and the first to fourth wires may be electrically separated from the third semiconductor chip 130 and the fourth semiconductor chip 140.

Referring to FIG. 4, a first wire W1′ may electrically connect a first data pad 115 of the first semiconductor chip 110 and a first bonding pad 101. The first wire W1′ may be electrically connected not only to the first data pad 115 of the first semiconductor chip 110 but also to a first data pad 125 of the second semiconductor chip 120, but may be separated from a first data pad of the third semiconductor chip 130 and a first data pad of the fourth semiconductor chip 140. Assuming an operation in which a data signal is input to the first data pad 115 of the first semiconductor chip 110, only capacitance due to an internal circuit of the first semiconductor chip 110 and capacitance due to an internal circuit of the second semiconductor chip 120 may act as a load for the first wire W1′.

In some implementations, a semiconductor package advantageous for a high-speed operation may be implemented by reducing the number of semiconductor chips commonly connected to one wire. First to fourth data pads of the first semiconductor chip 110 and first to fourth data pads of the second semiconductor chip 120 may be separated from first to fourth data pads of the third semiconductor chip 130 and first to fourth data pads of the fourth semiconductor chip 140. Therefore, a magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

FIG. 5 is a cross-sectional view illustrating an example of a cross-section of FIG. 3 in a B-B′direction.

Referring to FIG. 5, the upper surface of the third semiconductor chip 130 may be in contact with the lower surface of the fourth semiconductor chip 140. The lower surface of the third semiconductor chip 130 may be in contact with the upper surface of the second semiconductor chip 120. In the first direction, the third semiconductor chip 130 and the fourth semiconductor chip 140 may be disposed on an uppermost end among the plurality of semiconductor chips 150.

In some implementations, fifth to eighth data pads included in the third semiconductor chip 130 and fifth to eighth data pads included in the fourth semiconductor chip 140 may be electrically connected to each other through fifth to eighth wires, respectively, and the fifth to eighth wires may be electrically separated from the first semiconductor chip 110 and the second semiconductor chip 120.

Referring to FIG. 5, an eighth wire W2′ may electrically connect an eighth data pad 135 of the third semiconductor chip 130 and an eighth bonding pad 102. The eighth wire W2′ may be electrically connected not only to the eighth data pad 135 of the third semiconductor chip 130 but also to an eighth data pad 145 of the fourth semiconductor chip 140, but may be separated from an eighth data pad of the first semiconductor chip 110 and an eighth data pad of the second semiconductor chip 120. Assuming an operation in which a data signal is input to the eighth data pad 135 of the third semiconductor chip 130, only capacitance due to an internal circuit of the third semiconductor chip 130 and capacitance due to an internal circuit of the fourth semiconductor chip 140 may act as a load for the eighth wire W2′.

In some implementations, lengths of the first to fourth wires and lengths of the fifth to eighth wires may be different from each other. Referring to FIGS. 4 and 5 together, the first wire W1′ may be connected to the first data pad 115 of the first semiconductor chip 110, and the eighth wire W2′ may be connected to the eighth data pad 135 of the third semiconductor chip 130. In the first direction, perpendicular to the upper surface of the package substrate 105, the first semiconductor chip 110 may be closer to the bonding pad than the third semiconductor chip 130.

Therefore, a length of the first wire W1′ may be shorter than a length of the eighth wire W2′. In some implementations, a length of a 1-1 wire W1 and W1′ connecting all of the first data pad 115 of the first semiconductor chip 110 and the first data pad 125 of the second semiconductor chip 120 from the first bonding pad 101 may be shorter than a length of a 2-1 wire W2 and W2′ connecting all of the eighth bonding pad 102 to the eighth data pad 135 of the third semiconductor chip 130 and the eighth data pad 145 of the fourth semiconductor chip 140.

In some implementations, a semiconductor package advantageous for a high-speed operation may be implemented by reducing the number of semiconductor chips commonly connected to one wire. Fifth to eighth data pads of the third semiconductor chip 130 and fifth to eighth data pads of the fourth semiconductor chip 140 may be separated from fifth to eighth data pads of the first semiconductor chip 110 and fifth to eighth data pads of the second semiconductor chip 120. Therefore, a magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

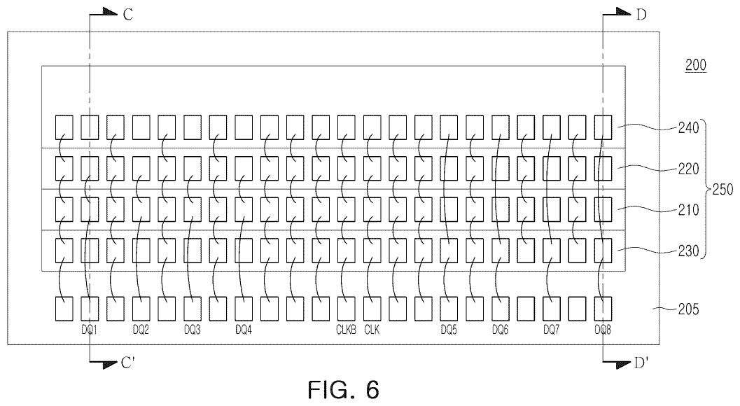

FIG. 6 is a plan view illustrating an example of a semiconductor package.

A semiconductor package 200 may include a package substrate 205, a plurality of semiconductor chips 250, and a plurality of wires. The plurality of semiconductor chips 250 may be mounted on an upper surface of the package substrate 205. The plurality of wires may connect a plurality of bonding pads and first to eighth data pads to each other.

The plurality of semiconductor chips 250 may include a first semiconductor chip 210, a second semiconductor chip 220, a third semiconductor chip 230, and a fourth semiconductor chip 240. The plurality of semiconductor chips 250 may be stacked in sequence of the third semiconductor chip 230, the first semiconductor chip 210, the second semiconductor chip 220, and the fourth semiconductor chip 240 on the upper surface of the package substrate 205.

In some implementations, assuming an operation in which a data signal is input to a first data pad DQ1 of the first semiconductor chip 210, an external memory controller or the like may transmit the data signal to the first data pad DQ1 of the first semiconductor chip 210 through a first wire. The first wire may be connected to the first data pad DQ1 of the first semiconductor chip 210 and a first data pad DQ1 of the second semiconductor chip 220, and may be electrically separated from a first data pad DQ1 of the third semiconductor chip 230 and a first data pad DQ1 of the fourth semiconductor chip 240. Therefore, the first wire may be subject to capacitance due to an internal circuit of the first semiconductor chip 210 and capacitance due to an internal circuit of the second semiconductor chip 220 as loads, and may not be affected by capacitance due to an internal circuit of the third semiconductor chip 230 and capacitance due to an internal circuit of the fourth semiconductor chip 240.

In some implementations, assuming an operation in which a data signal is input to a fifth data pad DQ5 of the third semiconductor chip 230, an external memory controller or the like may transmit the data signal to the fifth data pad DQ5 of the third semiconductor chip 230 through a fifth wire. The fifth wire may be connected to the fifth data pad DQ5 of the third semiconductor chip 230 and a fifth data pad DQ5 of the fourth semiconductor chip 240, and may be electrically separated from a fifth data pad DQ5 of the first semiconductor chip 210 and a fifth data pad DQ5 of the second semiconductor chip 220. Therefore, the fifth wire may be subject to capacitance due to an internal circuit of the third semiconductor chip 230 and capacitance due to an internal circuit of the fourth semiconductor chip 240 as loads, and may not be affected by capacitance due to an internal circuit of the first semiconductor chip 210 and capacitance due to an internal circuit of the second semiconductor chip 220.

Therefore, an input/output operation of a data signal through first to fourth data pads DQ1 to DQ4 included in the first semiconductor chip 210 or the second semiconductor chip 220, and an input/output operation of a data signal through fifth to eighth data pads DQ5 to DQ8 included in the third semiconductor chip 230 or the fourth semiconductor chip 240 may be performed at high speed, and performance of the semiconductor package may be improved by increasing an eye margin of a data signal.

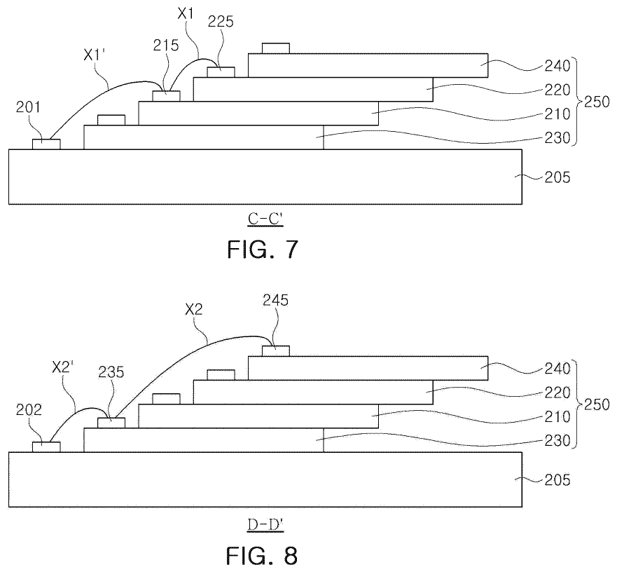

FIG. 7 is a cross-sectional view illustrating an example of a cross-section of FIG. 6 in a C-C′ direction.

In some implementations, the plurality of semiconductor chips 250 may have a structure in which they are stacked in a stepwise manner on the upper surface of the package substrate 205 in the first direction, perpendicular to the upper surface of the package substrate 205. The plurality of semiconductor chips 250 may be stacked in sequence of the third semiconductor chip 230, the first semiconductor chip 210, the second semiconductor chip 220, and the fourth semiconductor chip 240 on the upper surface of the package substrate 205.

In some implementations, a lower surface of the second semiconductor chip 220 may be in contact with an upper surface of the first semiconductor chip 210. At least one of the first semiconductor chip 210 or the second semiconductor chip 220 may be disposed between the third semiconductor chip 230 and the fourth semiconductor chip 240. Referring to FIG. 7, the first semiconductor chip 210 and the second semiconductor chip 220 may be disposed between the third semiconductor chip 230 and the fourth semiconductor chip 240.

In some implementations, first to fourth data pads included in the first semiconductor chip 210 and first to fourth data pads included in the second semiconductor chip 220 may be electrically connected to each other through first to fourth wires, respectively, and the first to fourth wires may be electrically separated from the third semiconductor chip 230 and the fourth semiconductor chip 240.

Referring to FIG. 7, a first wire X1′ may electrically connect a first data pad 215 of the first semiconductor chip 210 and a first bonding pad 201. The first wire X1′ may be electrically connected not only to the first data pad 215 of the first semiconductor chip 210 but also to a first data pad 225 of the second semiconductor chip 220, but may be separated from a first data pad of the third semiconductor chip 230 and a first data pad of the fourth semiconductor chip 240. Assuming an operation in which a data signal is input to the first data pad 215 of the first semiconductor chip 210, only capacitance due to an internal circuit of the first semiconductor chip 210 and capacitance due to an internal circuit of the second semiconductor chip 220 may act as a load for the first wire X1′.

In some implementations, a semiconductor package advantageous for a high-speed operation may be implemented by reducing the number of semiconductor chips commonly connected to one wire. First to fourth data pads of the first semiconductor chip 210 and first to fourth data pads of the second semiconductor chip 220 may be separated from first to fourth data pads of the third semiconductor chip 230 and first to fourth data pads of the fourth semiconductor chip 240. Therefore, a magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

FIG. 8 is a cross-sectional view illustrating an example of a cross-section of FIG. 6 in a D-D′ direction.

In some implementations, at least one of the first semiconductor chip 210 or the second semiconductor chip 220 may be disposed between the third semiconductor chip 230 and the fourth semiconductor chip 240. Referring to FIG. 8, the first semiconductor chip 210 and the second semiconductor chip 220 may be disposed between the third semiconductor chip 230 and the fourth semiconductor chip 240. In some implementations, an upper surface of the third semiconductor chip 230 may be in contact with a lower surface of the first semiconductor chip 210, and a lower surface of the fourth semiconductor chip 240 may be in contact with an upper surface of the second semiconductor chip 220.

In some implementations, fifth to eighth data pads included in the third semiconductor chip 230 and fifth to eighth data pads included in the fourth semiconductor chip 240 may be electrically connected to each other through fifth to eighth wires, respectively, and the fifth to eighth wires may be electrically separated from the first semiconductor chip 210 and the second semiconductor chip 220.

Referring to FIG. 8, an eighth wire X2′ may electrically connect an eighth data pad 235 of the third semiconductor chip 230 and an eighth bonding pad 202. The eighth wire X2′ may be electrically connected not only to the eighth data pad 235 of the third semiconductor chip 230 but also to an eighth data pad 245 of the fourth semiconductor chip 240, but may be separated from an eighth data pad of the first semiconductor chip 210 and an eighth data pad of the second semiconductor chip 220. Assuming an operation in which a data signal is input to the eighth data pad 235 of the third semiconductor chip 230, only capacitance due to an internal circuit of the third semiconductor chip 230 and capacitance due to an internal circuit of the fourth semiconductor chip 240 may act as a load for the eighth wire X2′.

In some implementations, lengths of the first to fourth wires and lengths of the fifth to eighth wires may be different from each other. Referring to FIGS. 7 and 8 together, the first wire X1′ may be connected to the first data pad 215 of the first semiconductor chip 210, and the eighth wire X2′ may be connected to the eighth data pad 235 of the third semiconductor chip 230. In the first direction, perpendicular to the upper surface of the package substrate 205, the first semiconductor chip 210 may be further from the bonding pad than the third semiconductor chip 230. Therefore, a length of the first wire X1′ may be longer than a length of the eighth wire X2′. In some implementations, a length of a 1-1 wire X1 and X1′ connecting all of the first data pad 215 of the first semiconductor chip 210 and the first data pad 225 of the second semiconductor chip 220 from the first bonding pad 201 may be shorter than a length of a 2-1 wire X2 and X2′ connecting all of the eighth bonding pad 202 to the eighth data pad 235 of the third semiconductor chip 230 and the eighth data pad 245 of the fourth semiconductor chip 240.

In some implementations, a semiconductor package advantageous for a high-speed operation may be implemented by reducing the number of semiconductor chips commonly connected to one wire. Fifth to eighth data pads of the third semiconductor chip 230 and fifth to eighth data pads of the fourth semiconductor chip 240 may be separated from fifth to eighth data pads of the first semiconductor chip 210 and fifth to eighth data pads of the second semiconductor chip 220. Therefore, a magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

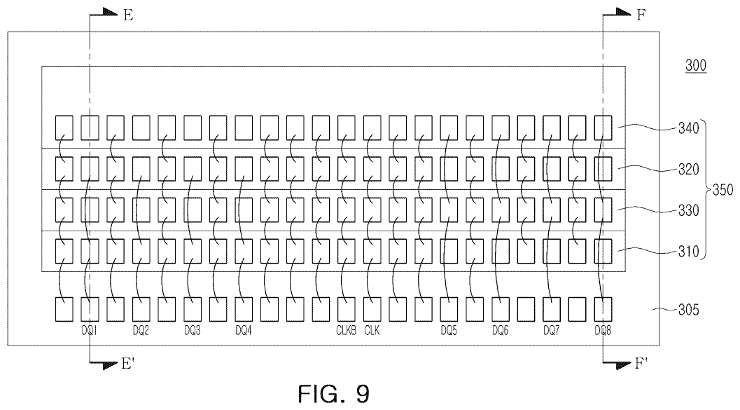

FIG. 9 is a plan view illustrating an example of a semiconductor package.

A semiconductor package 300 may include a package substrate 305, a plurality of semiconductor chips 350, and a plurality of wires. The plurality of semiconductor chips 350 may be mounted on an upper surface of the package substrate 305. The plurality of wires may connect a plurality of bonding pads and first to eighth data pads to each other.

The plurality of semiconductor chips 350 may include a first semiconductor chip 310, a second semiconductor chip 320, a third semiconductor chip 330, and a fourth semiconductor chip 340. The first semiconductor chip 310, the third semiconductor chip 330, the second semiconductor chip 320, and the fourth semiconductor chip 340 may be stacked in sequence on the upper surface of the package substrate 305.

In some implementations, a first wire may be connected to a first data pad DQ1 of the first semiconductor chip 310 and a first data pad DQ1 of the second semiconductor chip 320, and may be electrically separated from a first data pad DQ1 of the third semiconductor chip 330 and a first data pad DQ1 of the fourth semiconductor chip 340. Therefore, the first wire may be subject to capacitance due to an internal circuit of the first semiconductor chip 310 and capacitance due to an internal circuit of the second semiconductor chip 320 as loads, and may not be affected by capacitance due to an internal circuit of the third semiconductor chip 330 and capacitance due to an internal circuit of the fourth semiconductor chip 340.

In some implementations, a fifth wire may be connected to a fifth data pad DQ5 of the third semiconductor chip 330 and a fifth data pad DQ5 of the fourth semiconductor chip 340, and may be electrically separated from a fifth data pad DQ5 of the first semiconductor chip 310 and a fifth data pad DQ5 of the second semiconductor chip 320. Therefore, the fifth wire may be subject to capacitance due to an internal circuit of the third semiconductor chip 330 and capacitance due to an internal circuit of the fourth semiconductor chip 340 as loads, and may not be affected by capacitance due to an internal circuit of the first semiconductor chip 310 and capacitance due to an internal circuit of the second semiconductor chip 320.

Therefore, an input/output operation of a data signal through first to fourth data pads DQ1 to DQ4 included in the first semiconductor chip 310 or the second semiconductor chip 320, and an input/output operation of a data signal through fifth to eighth data pads DQ5 to DQ8 included in the third semiconductor chip 330 or the fourth semiconductor chip 340 may be performed at a high speed, and performance of the semiconductor package may be improved by increasing an eye margin of a data signal.

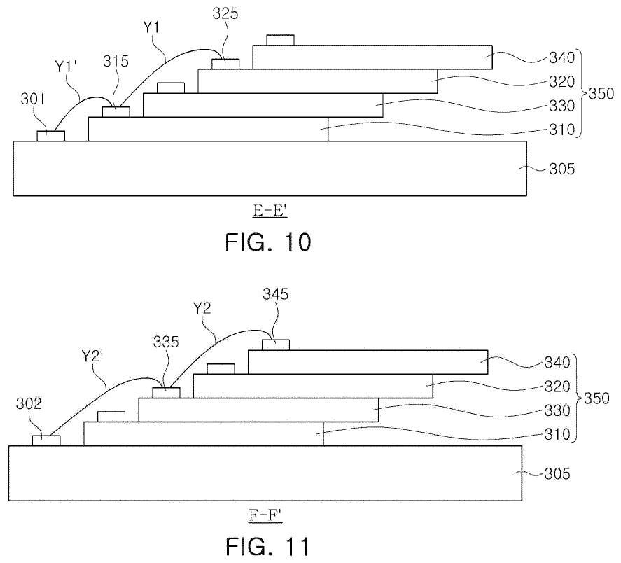

FIG. 10 is a cross-sectional view illustrating an example of a cross-section of FIG. 9 in an E-E′ direction.

In some implementations, the plurality of semiconductor chips 350 may have a structure in which they are stacked in a stepwise manner on the upper surface of the package substrate 305 in the first direction, perpendicular to the upper surface of the package substrate 305. The plurality of semiconductor chips 350 may be stacked in sequence of the first semiconductor chip 310, the third semiconductor chip 330, the second semiconductor chip 320, and the fourth semiconductor chip 340.

In some implementations, at least one of the third semiconductor chip 330 or the fourth semiconductor chip 340 may be disposed between the first semiconductor chip 310 and the second semiconductor chip 320. Referring to FIG. 10, the third semiconductor chip 330 may be disposed between the first semiconductor chip 310 and the second semiconductor chip 320. The first semiconductor chip 310 and the second semiconductor chip 320 may not contact each other.

In some implementations, first to fourth data pads included in the first semiconductor chip 310 and first to fourth data pads included in the second semiconductor chip 320 may be electrically connected to each other through first to fourth wires, respectively, and the first to fourth wires may be electrically separated from the third semiconductor chip 330 and the fourth semiconductor chip 340.

Referring to FIG. 10, a first wire Y1′ may electrically connect a first bonding pad 301, a first data pad 315 of the first semiconductor chip 310, and a first data pad 325 of the second semiconductor chip 320, but may be separated from a first data pad of the third semiconductor chip 330 and a first data pad of the fourth semiconductor chip 340. Assuming an operation in which a data signal is input to the first data pad 315 of the first semiconductor chip 310, only capacitance due to an internal circuit of the first semiconductor chip 310 and capacitance due to an internal circuit of the second semiconductor chip 320 may act as a load on the first wire Y1′.

In some implementations, a semiconductor package advantageous for a high-speed operation may be implemented by reducing the number of semiconductor chips commonly connected to one wire. A magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

FIG. 11 is a cross-sectional view illustrating an example of a cross-section of FIG. 9 in an F-F′ direction.

In some implementations, at least one of the first semiconductor chip 310 or the second semiconductor chip 320 may be disposed between the third semiconductor chip 330 and the fourth semiconductor chip 340. Referring to FIG. 11, the second semiconductor chip 320 may be disposed between the third semiconductor chip 330 and the fourth semiconductor chip 340.

In some implementations, fifth to eighth data pads included in the third semiconductor chip 330 and fifth to eighth data pads included in the fourth semiconductor chip 340 may be electrically connected to each other through fifth to eighth wires, respectively, and the fifth to eighth wires may be electrically separated from the first semiconductor chip 310 and the second semiconductor chip 320.

Referring to FIG. 11, an eighth wire Y2′ may electrically connect an eighth data pad 335 of the third semiconductor chip 330 and an eighth bonding pad 302. The eighth wire Y2′ may be electrically connected not only to the eighth data pad 335 of the third semiconductor chip 330 but also to an eighth data pad 345 of the fourth semiconductor chip 340, but may be separated from an eighth data pad of the first semiconductor chip 310 and an eighth data pad of the second semiconductor chip 320. Assuming an operation in which a data signal is input to the eighth data pad 335 of the third semiconductor chip 330, only capacitance due to an internal circuit of the third semiconductor chip 330 and capacitance due to an internal circuit of the fourth semiconductor chip 340 may act as a load for the eighth wire Y2′.

In some implementations, lengths of the first to fourth wires and lengths of the fifth to eighth wires may be different from each other. Referring to FIGS. 10 and 11 together, a length of the first wire Y1′ may be shorter than a length of the eighth wire Y2′. In some implementations, a length of a 1-1 wire Y1 and Y1′ connecting all of the first bonding pad 301 to the first data pad 315 of the first semiconductor chip 310 and the first data pad 325 of the second semiconductor chip 320 may be shorter than a length of a 2-1 wire Y2 and Y2′ connecting all of the eighth bonding pad 302 to the eighth data pad 335 of the third semiconductor chip 330 and the eighth data pad 345 of the fourth semiconductor chip 340.

In some implementations, fifth to eighth data pads of the third semiconductor chip 330 and fifth to eighth data pads of the fourth semiconductor chip 340 may be separated from fifth to eighth data pads of the first semiconductor chip 310 and fifth to eighth data pads of the second semiconductor chip 320. Therefore, a magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

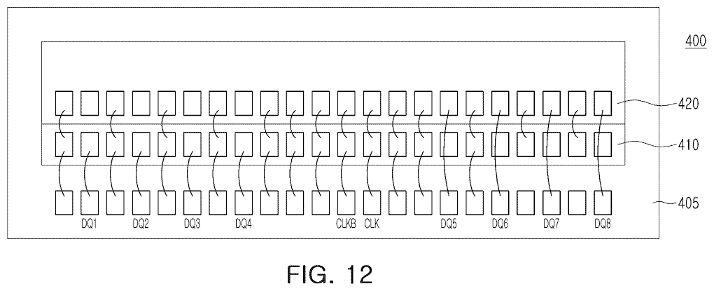

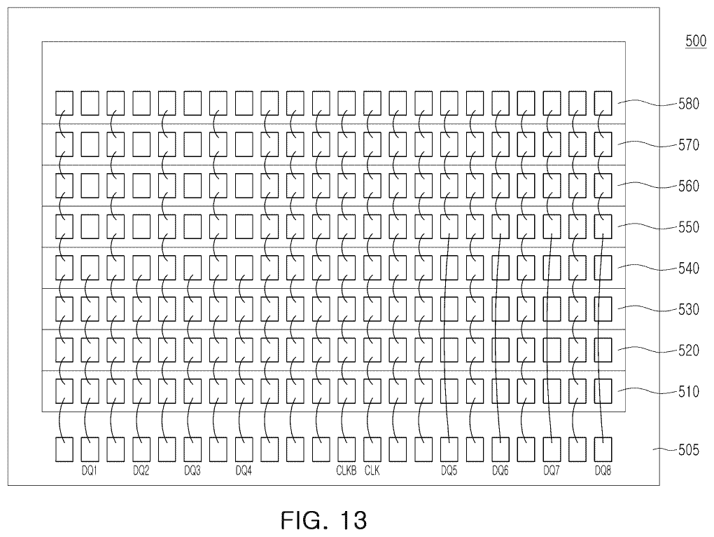

FIGS. 12 and 13 are plan views illustrating an example of a semiconductor package.

A semiconductor package may include a plurality of semiconductor chips. The number of the plurality of semiconductor chips is not limited to four, and may be more or less than four.

Referring to FIG. 12, a first semiconductor chip 410 and a second semiconductor chip 420 may be stacked on an upper surface of a package substrate 405. The package substrate 405 may include a plurality of bonding pads, and the first semiconductor chip 410 and the second semiconductor chip 420 may include a plurality of pads. A plurality of bonding wires may respectively connect the plurality of bonding pads and data pads.

First to fourth data pads DQ1 to DQ4 of the first semiconductor chip 410 may be connected to first to fourth bonding pads through first to fourth wires, but may be separated from first to fourth data pads DQ1 to DQ4 of the second semiconductor chip 420. Fifth to eighth data pads DQ5 to DQ8 of the second semiconductor chip 420 may be connected to fifth to eighth bonding pads through fifth to eighth wires, but may be separated from fifth to eighth data pads DQ5 to DQ8 of the first semiconductor chip 410.

In some implementations, a semiconductor package advantageous for a high-speed operation may be implemented by reducing the number of semiconductor chips commonly connected to one wire. A magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

Referring to FIG. 13, first to eighth semiconductor chips 510, 520, 530, 540, 550, 560, 570, and 580 may be stacked on an upper surface of a package substrate 505. The package substrate 505 may include a plurality of bonding pads, and the first to eighth semiconductor chips 510, 520, 530, 540, 550, 560, 570, and 580 may include a plurality of pads. A plurality of wires may respectively connect the plurality of bonding pads and data pads.

First to fourth data pads DQ1 to DQ4 of the first to fourth semiconductor chips 510, 520, 530, and 540 may be connected to each other through first to fourth wires, but may be separated from first to fourth data pads DQ1 to DQ4 of the fifth to eighth semiconductor chips 550, 560, 570, and 580. Fifth to eighth data pads DQ5 to DQ8 of the fifth to eighth semiconductor chips 550, 560, 570, and 580 may be connected to each other through fifth to eighth wires, but may be separated from fifth to eighth data pads DQ5 to DQ8 of the first to fourth semiconductor chips 510, 520, 530, and 540.

In some implementations, a semiconductor package advantageous for a high-speed operation may be implemented by reducing the number of semiconductor chips commonly connected to one wire. A magnitude of input/output capacitance affecting input/output of a data signal by each of the semiconductor chips may be reduced, an input/output operation of the data signal may be performed at a high speed, and an eye margin of the data signal may increase to improve performance of the semiconductor package.

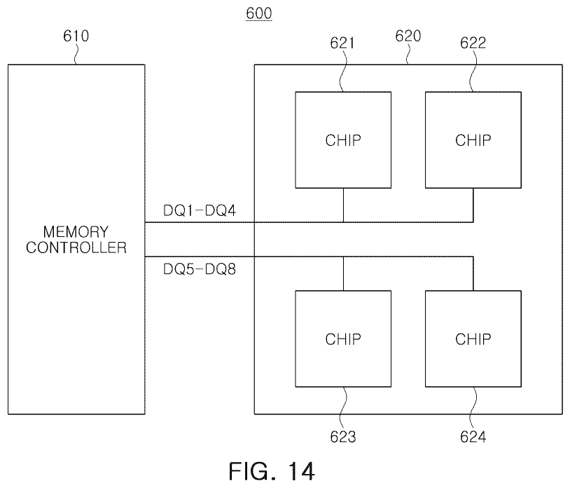

FIG. 14 is a block diagram illustrating an example of a memory device.

In some implementations, a memory device 600 may include a memory controller 610 and a non-volatile memory 620. The non-volatile memory 620 may include a semiconductor package in which a plurality of semiconductor chips are stacked. Referring to FIG. 14, the non-volatile memory 620 may include first to fourth semiconductor chips 621 to 624.

In some implementations, the memory controller 610 may transmit a data signal to data pads of the semiconductor chips 621 to 624 through a wire. For example, the memory controller 610 may transmit a 4-bit first data signal to first to fourth data pads of the first semiconductor chip 621 and first to fourth data pads of the second semiconductor chip 622, and may transmit a 4-bit second data signal, different from the first data signal, to fifth to eighth data pads of the third semiconductor chip 623 and fifth to eighth data pads of the fourth semiconductor chip 624.

The plurality of semiconductor chips may receive a clock signal, which is the same, through at least one wire, and according to the clock signal, the first semiconductor chip 621 and the second semiconductor chip 622 may transmit the first data signal to the memory controller 610 through the first to fourth data pads, and simultaneously, the third semiconductor chip 623 and the fourth semiconductor chip 624 may transmit the second data signal to the memory controller 610 through the fifth to eighth data pads.

The memory device 600 may be a double data rate (DDR) memory, and may transmit data at a rising edge and a falling edge of the clock signal. For example, the memory controller 610 may transmit the 4-bit first data signal to the first to fourth data pads of the first semiconductor chip 621 and the first to fourth data pads of the second semiconductor chip 622, respectively, at a rising edge and a falling edge of the clock signal, and may transmit the 4-bit second data signal to the fifth to eighth data pads of the third semiconductor chip 623 and the fifth to eighth data pads of the fourth semiconductor chip 624.

In some implementations, the memory controller 610 may divide an 8-bit data signal into 4 bits, and may transmit the same to each of the semiconductor chips, such that the number of semiconductor chips transmitted through one channel may be reduced. Therefore, a magnitude of input/output capacitance affecting input/output of a data signal may be reduced, and a semiconductor package advantageous for a high-speed operation having improved reliability may be provided.

According to some implementations, a portion of a plurality of semiconductor chips may use only a first data pad group among a plurality of data pads, and the other portion of the plurality of semiconductor chips may use only a second data pad group, different from the first data pad group, among the plurality of data pads. The first data pad group included in the portion of the plurality of semiconductor chips may be separated from the first data pad group included in the other portion of the plurality of semiconductor chips. Therefore, a magnitude of input/output capacitance affecting input/output of a data signal by each of the semiconductor chips may be reduced, and a semiconductor package having improved reliability and advantageous for a high-speed operation may be implemented.

Various advantages and effects of the present disclosure may not be limited to the above-described contents, and will be more easily understood in the process of explaining specific example implementations.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A semiconductor package comprising:
a package substrate including a plurality of bonding pads;
a plurality of semiconductor chips on an upper surface of the package substrate, each semiconductor chip of the plurality of semiconductor chips including a plurality of pads, wherein each pad of the plurality of pads includes a first data pad, a second data pad, a third data pad, and a fourth data pad; and
a plurality of wires connecting the plurality of pads,
wherein the plurality of semiconductor chips include a first semiconductor chip, a second semiconductor chip, a third semiconductor chip, and a fourth semiconductor chip,
wherein the first data pad in the first semiconductor chip and the first data pad in the second semiconductor chip are connected through a first wire,
wherein the second data pad in the first semiconductor chip and the second data pad in the second semiconductor chip are connected through a second wire,
wherein the third data pad in the first semiconductor chip and the third data pad in the second semiconductor chip are connected through a third wire,
wherein the fourth data pad in the first semiconductor chip and the fourth data pad in the second semiconductor chip are connected through a fourth wire, and
wherein the first wire, the second wire, the third wire, and the fourth wire are separated from the third semiconductor chip and the fourth semiconductor chip.

2. The semiconductor package of claim 1, wherein, in a first direction perpendicular to the upper surface of the package substrate, the plurality of semiconductor chips are stacked in a stepwise manner.

3. The semiconductor package of claim 1, wherein each pad of the plurality of pads includes a fifth data pad, a sixth data pad, a seventh data pad, and an eighth data pad, and
wherein the first data pad, the second data pad, the third data pad, the fourth data pad, the fifth data pad, the sixth data pad, the seventh data pad, and the eighth data pad are not adjacent to each other.

4. The semiconductor package of claim 1, wherein each pad of the plurality of pads includes a fifth data pad, a sixth data pad, a seventh data pad, and an eighth data pad, and
wherein at least one pad configured to provide a power voltage or a ground voltage is disposed between the first data pad, the second data pad, the third data pad, the fourth data pad, the fifth data pad, the sixth data pad, the seventh data pad, and the eighth data pad.

5. The semiconductor package of claim 1, wherein each pad of the plurality of pads includes a fifth data pad, a sixth data pad, a seventh data pad, and an eighth data pad, and
wherein a pair of pads configured to provide a differential clock signal are disposed between the fourth data pad and the fifth data pad.

6. The semiconductor package of claim 5, wherein the pair of pads included in each semiconductor chip of the plurality of semiconductor chips are connected with each other through at least one wire among the plurality of wires.

7. The semiconductor package of claim 5, wherein at least one pad configured to provide a power voltage or a ground voltage is disposed between the fourth data pad and the pair of pads.

8. The semiconductor package of claim 5, wherein at least one pad configured to provide a power voltage or a ground voltage is disposed between the fifth data pad and the pair of pads.

9. The semiconductor package of claim 1, wherein a lower surface of the second semiconductor chip contacts an upper surface of the first semiconductor chip.

10. The semiconductor package of claim 9, wherein at least one of the third semiconductor chip or the fourth semiconductor chip is disposed on an upper surface of the second semiconductor chip.

11. The semiconductor package of claim 9, wherein at least one of the third semiconductor chip or the fourth semiconductor chip is disposed on a lower surface of the first semiconductor chip.

12. The semiconductor package of claim 1, wherein at least one of the third semiconductor chip or the fourth semiconductor chip is disposed between the first semiconductor chip and the second semiconductor chip.

13. The semiconductor package of claim 12, wherein, in a first direction perpendicular to the upper surface of the package substrate, the first semiconductor chip is disposed lower than the second semiconductor chip, and at least one of the third semiconductor chip or the fourth semiconductor chip is disposed lower than the first semiconductor chip.

14. The semiconductor package of claim 12, wherein, in a first direction perpendicular to the upper surface of the package substrate, the first semiconductor chip is disposed lower than the second semiconductor chip, and at least one of the third semiconductor chip or the fourth semiconductor chip is disposed upper than the second semiconductor chip.

15. The semiconductor package of claim 1, wherein, in a first direction perpendicular to the upper surface of the package substrate, the first semiconductor chip and the second semiconductor chip are disposed on a lowermost level among the plurality of semiconductor chips, and wherein the third semiconductor chip and the fourth semiconductor chip are disposed on an uppermost level among the plurality of semiconductor chips.

16. The semiconductor package of claim 1, wherein, in a first direction perpendicular to the upper surface of the package substrate, the first semiconductor chip and the second semiconductor chip are disposed on an uppermost level among the plurality of semiconductor chips, and wherein the third semiconductor chip and the fourth semiconductor chip are disposed on a lowermost level among the plurality of semiconductor chips.

17. A semiconductor package comprising:
a package substrate including a plurality of bonding pads;
a plurality of semiconductor chips on an upper surface of the package substrate, each semiconductor chip of the plurality of semiconductor chips including a plurality of pads, wherein each pad of the plurality of pads includes a first data pad, a second data pad, a third data pad, a fourth data pad, a fifth data pad, a sixth data pad, a seventh data pad, and an eighth data pad; and
a plurality of wires connecting the plurality of pads,
wherein the plurality of semiconductor chips include a first semiconductor chip, a second semiconductor chip, a third semiconductor chip, and a fourth semiconductor chip,
wherein the first data pad in the first semiconductor chip and the first data pad in the second semiconductor chip are connected through a first wire,
wherein the second data pad in the first semiconductor chip and the second data pad in the second semiconductor chip are connected through a second wire,
wherein the third data pad in the first semiconductor chip and the third data pad in the second semiconductor chip are connected through a third wire,
wherein the fourth data pad in the first semiconductor chip and the fourth data pad in the second semiconductor chip are connected through a fourth wire,
wherein the first wire, the second wire, the third wire, and the fourth wire are separated from the third semiconductor chip and the fourth semiconductor chip,
wherein the fifth data pad in the third semiconductor chip and the fifth data pad in the fourth semiconductor chip are connected through a fifth wire,
wherein the sixth data pad in the third semiconductor chip and the sixth data pad in the fourth semiconductor chip are connected through a sixth wire,
wherein the seventh data pad in the third semiconductor chip and the seventh data pad in the fourth semiconductor chip are connected through a seventh wire,
wherein the eighth data pad in the third semiconductor chip and the eighth data pad in the fourth semiconductor chip are connected through an eighth wire,
wherein the fifth wire, the sixth wire, the seventh wire, and the eighth wire are separated from the first semiconductor chip and the second semiconductor chip, and
wherein lengths of the first wire, the second wire, the third wire, and the fourth wire are different from lengths of the fifth wire, the sixth wire, the seventh wire, and the eighth wire.

18. The semiconductor package of claim 17, wherein the lengths of the first wire, the second wire, the third wire, and the fourth wire are longer than the lengths of the fifth wire, the sixth wire, the seventh wire, and the eighth wire.

19. The semiconductor package of claim 17, wherein the lengths of the first wire, the second wire, the third wire, and the fourth wire are shorter than the lengths of the fifth wire, the sixth wire, the seventh wire, and the eighth wire.

20. A semiconductor package comprising:
a package substrate including a plurality of bonding pads;
a plurality of semiconductor chips on an upper surface of the package substrate, each semiconductor chip of the plurality of semiconductor chips including a plurality of pads, wherein each pad of the plurality of pads includes a first data pad, a second data pad, a third data pad, a fourth data pad, a fifth data pad, a sixth data pad, a seventh data pad, an eighth data pad; and
a plurality of wires connecting the plurality of pads,
wherein the plurality of semiconductor chips include a first semiconductor chip, a second semiconductor chip, a third semiconductor chip, and a fourth semiconductor chip,
wherein the first data pad in the first semiconductor chip and the first data pad in the second semiconductor chip are connected through a first wire,
wherein the second data pad in the first semiconductor chip and the second data pad in the second semiconductor chip are connected through a second wire,
wherein the third data pad in the first semiconductor chip and the third data pad in the second semiconductor chip are connected through a third wire,
wherein the fourth data pad in the first semiconductor chip and the fourth data pad in the second semiconductor chip are connected through a fourth wire,
wherein the first wire, the second wire, the third wire, and the fourth wire are separated from the third semiconductor chip and the fourth semiconductor chip,
wherein the plurality of semiconductor chips are configured to receive a same clock signal through at least one wire,
wherein the first semiconductor chip and the second semiconductor chip are configured to, based on the same clock signal, transmit a first data signal through the first data pad, the second data pad, the third data pad, and the fourth data pad, and
wherein the third semiconductor chip and the fourth semiconductor chip are configured to, based on the same clock signal, simultaneously transmit a second data signal through the fifth data pad, the sixth data pad, the seventh data pad, and the eighth data pad.
